(19) United States
(12) Patent Application Publication
(10) Pub. No.: US 2026/0164818 A1
(43) Pub. Date: Jun. 11, 2026

(54) SEMICONDUCTOR DETECTION MODULE, SORTING MACHINE AND SPECTROMETER

(71) Applicant: KETEK GmbH Halbleiter-und Reinraumtechnik, Muenchen (DE)

(72) Inventors: Michael Darius Fraczek, Pliening (DE); Peter Iskra, Neubiberg (DE); Werner Buttler, Essen (DE); Florian Wiest, Muenchen (DE); Andreas Pahlke, Brunnthal (DE)

(21) Appl. No.: 19/181,129

(22) Filed: Apr. 16, 2025

Related U.S. Application Data
(63) Continuation-in-part of application No. 18/642,373, filed on Apr. 22, 2024.

(51) Int. Cl. H10F 39/18; G01T 1/24; H10F 39/00

(52) U.S. Cl. CPC H10F 39/1895; G01T 1/241; G01T 1/247; H10F 39/804; H10F 39/811

(57) ABSTRACT

In an embodiment, a semiconductor detection module includes at least one semiconductor body and a plurality of read-out electrodes assigned to the at least one semiconductor body. Each read-out electrode is configured to provide a raw detector signal. The semiconductor detection module further comprises a plurality of evaluation units, each evaluation unit configured to process the raw detector signal, which comprises a sequence of signal peaks, by assigning the signal peaks to at least one region of interest. Each evaluation unit is further configured to provide a number of counts in each region of interest as an output signal. Each evaluation unit is assigned to exactly one read-out electrode.

### CROSS-REFERENCE TO RELATED APPLICATIONS

This application is a continuation-in-part application of U.S. application Ser. No. 18/642,373, filed on Apr. 22, 2024, which application is hereby incorporated herein by reference in its entirety.

### TECHNICAL FIELD

A semiconductor detection module is specified. Furthermore, a sorting machine, a spectrometer and a synchrotron are specified.

### SUMMARY

Embodiments provide a semiconductor detection module that in particular enables an increased counting rate for detecting electromagnetic radiation, in particular X-rays. Further embodiments provide a sorting machine, a spectrometer and a synchrotron, each comprising such a detection module.

According to at least one embodiment, the semiconductor detection module comprises at least one semiconductor body and a plurality of read-out electrodes assigned to the at least one semiconductor body. For example, each of the read-out electrodes together with the semiconductor body or at least a part of the semiconductor body forms a detector element. In particular, each detector element comprises one, preferably exactly one read-out electrode and the semiconductor body.

The semiconductor body is, for example, based on silicon. For example, the semiconductor body is n-doped.

In particular, each detector element may act as a semiconductor detector by means of which incident electromagnetic radiation can be detected. The read-out electrode is, for example, an anode. During operation, electromagnetic radiation, in particular X-rays, may generate free charge carriers on the semiconductor body. By applying an operation voltage to the semiconductor body, an electrical field may be formed in the semiconductor body by which the charge carriers may be guided to the read-out electrode. To achieve this electrical field, also referred to as a drift field, the semiconductor detection module may comprise at least one contact structure for suitably electrically contacting the semiconductor body.

For example, each detector element may act as or form a silicon drift detector. It is also possible that each detector element acts as a PIN-diode or another suitable semiconductor detector.

According to at least one embodiment, the read-out electrodes are configured to provide one raw detector signal per read-out electrode. In other words, each read-out electrode provides a detector signal during operation.

Each detector signal in particular comprises a sequence of signal peaks. In particular, the signal peaks correspond to incident electromagnetic radiation on the detector. Thereby, a height of the signal peaks and/or preferably an area of the signal peaks may be associated with a photon energy of the electromagnetic radiation. For example, the height or, more specific, the area of each signal peak corresponds to a charge that is generated when detecting the photon and forming the signal peak. In particular, photons with a higher energy generate more charges than photons with a lower energy during a detection event. Consequently, higher energy photons generate a signal peak with a larger area. In particular, each signal peak corresponds to one photon detected by the detector and the height and/or area of this signal peak corresponds to the energy of the photon.

According to at least one embodiment, the semiconductor detection module comprises a plurality of evaluation units. In particular, each evaluation unit is assigned to exactly one read-out electrode.

Each evaluation unit is configured to process the raw detector signal comprising the sequence of signal peaks by assigning the signal peaks to at least one region of interest. Each evaluation unit is further configured to provide a number of counts in each region of interest as an output signal. In particular, the signal peaks are assigned or binned to the regions of interest based on the height and/or the area of the signal peaks. In other words, the signal peaks are in particular binned depending on the energy of the detected photon to which the signal peak corresponds. The number of counts in particular corresponds to the number of signal peaks assigned to a certain region of interest.

In particular, to generate the detector signal, each evaluation unit is configured to perform a method for processing the detector signal as described in U.S. patent application Ser. No. 18/642,373. In particular, the evaluation unit is configured to perform the method for processing the detector signal according to one or more of the embodiments disclosed in U.S. patent application Ser. No. 18/642,373, for example as described in paragraphs [0003] to [0039].

During operation, incident photons may generate free charge carriers in the semiconductor body, which are guided to the read-out electrode. At the read-out electrode the charge carriers may be collected and a signal peak as part of the detector signal is provided. The detector signal is in particular provided to the evaluation unit, which processes, assigns and bins the signal peaks in the at least one region of interest and further provides the number of counts in each region of interest as the output signal. Since each evaluation unit is assigned to exactly one read-out electrode, the number of output signals in particular corresponds to the number of read-out electrodes.

Furthermore, the evaluation unit and semiconductor detection module described herein may additionally essentially comprise similar features as the evaluation unit and the detection module disclosed in U.S. patent application Ser. No. 18/642,373, respectively, and/or may comprise components as disclosed in U.S. patent application Ser. No. 18/642,373, in particular in paragraphs [0041] to [0066.

Preferably, the evaluation unit comprises an integration unit, a shaping unit, a comparator unit, a counter unit and a storage unit as described in paragraphs [0041] to [0050] of U.S. patent application Ser. No. 18/642,373.

In at least one embodiment, the semiconductor detection module comprises at least one semiconductor body and a plurality of read-out electrodes assigned to the at least one semiconductor body. Each read-out electrode is configured to provide a raw detector signal. The semiconductor detection module further comprises a plurality of evaluation units, each being configured to process the raw detector signal, which comprises a sequence of signal peaks, by assigning the signal peaks to at least one region of interest. Each evaluation unit is further configured to provide a number of counts in each region of interest as an output signal. Each evaluation unit is assigned to exactly one read-out electrode.

The semiconductor detection module described herein is based on the following technical considerations. A counting rate of a semiconductor detector such as a silicon drift detector is in particular limited by a pulse length of a pulse corresponding to a detection event after signal shaping. For example, the pulse length may be defined as a period of time in which an amplitude of a corresponding pulse is higher than 5% of a maximal amplitude of this pulse.

For example, if, during the pulse length corresponding to a first detection event, a second detection event occurs, this second detection event or even the first and second detection events have to be left unconsidered, since the peaks cannot be unambiguously assigned to one detection event. Hence, a maximal counting rate is in good approximation limited to a reciprocal of the pulse length.

The semiconductor detection module described herein makes use of the idea of increasing the counting rate by providing a plurality of read-out electrodes, each providing a detector signal. Thus, an area of the semiconductor detection module may be segmented. If, for example, N read-out electrodes are provided, the maximal counting rate Zₘₐₓ may be determined by N/tₚ, where tₚ denotes the pulse length. However, by increasing the number of read-out electrodes and thus the number of detector signals, an amount of data to be processed to analyze the incident radiation also significantly increases.

By using the evaluation unit described herein, the amount of data to be processed can be significantly reduced, since only signal peaks corresponding to regions of interest are considered, as described in paragraphs [0014] to [0016] of U.S. patent application Ser. No. 18/642,373. For example, for each read-out electrode only 2 N_{ROI} values have to be processed and analyzed, where N_{ROI} denotes the regions of interest associated with each read-out electrode. For example, N_{ROI} is 32. Compared to common detection applications using digital pulse processors, which for example utilize 4096 channels or more, the amount of data to be processed can be thus significantly reduced by, for example, a factor of 100 or more.

In particular, proceeding the detector signal of each read-out electrode is carried out by the corresponding evaluation unit.

Consequently, the counting rate can be significantly increased, since the amount of data can be kept comparably small by using the evaluation unit described here. Therefore, the detection module can be formed in a comparably compact housing. As a result, in various applications, the semiconductor detection module described herein may be used instead of common detectors. Thereby advantageously only comparably small or essentially no adaptions of the application may be required.

According to at least one embodiment, the semiconductor detection module comprises a plurality of semiconductor bodies, wherein at least one read-out electrode is assigned to each semiconductor body. For example, a number of semiconductor bodies is smaller than a number of read-out electrodes, so that more than one read-out electrode is assigned to at least one semiconductor body.

According to at least one embodiment, the number of semiconductor bodies equals the number of read-out electrodes so that each semiconductor body is assigned to exactly one read-out electrode and vice versa.

According to at least one embodiment, the semiconductor detection module comprises exactly one semiconductor body, wherein all read-out electrodes are assigned to the semiconductor body.

According to at least one embodiment, the semiconductor detection module comprises a processor unit configured to process the output signals of the evaluation units and to provide a single processed data signal. In particular, the processor unit may receive the output signals provided by the evaluation units, corresponding to the detector signals of each read-out electrode, as an input and process these output signals to a single data signal. Thus, the semiconductor detection module may provide the single data signal as a one-channel output. This advantageously allows the usage of the semiconductor detection module in various existing applications without significant adaptions to the application.

Furthermore, by processing the output signals by the processor unit, the amount of data can advantageously be further reduced.

In particular, the processor unit may be configured to read-out the number of counts of the regions of interest included in the output signals and corresponding to the detector signals.

According to at least one embodiment, the processor unit is configured to arithmetically process the number of counts of similar regions of interest of different output signals. For example, the processor unit may be configured to calculate an average of the number of counts of each region of interest, add the number of counts of each region of interest or calculate ratios of certain numbers of counts of different regions of interest of, for example, different or the same detector signals, taking into account the number of counts of each output signal.

According to at least one embodiment, the processor unit is configured to monitor a variation of the number of counts corresponding to the regions of interest of at least one output signal. Thus, the processor unit may detect and monitor variations in the number of counts.

According to at least one embodiment, the processor unit is configured to detect and process charge sharing events. In particular, a charge sharing event occurs when the charge of a detection event is split into two detector segments. This causes the single detection event to be detected as two detection events with less photon energy. However, for analysis, it is not clear whether the signals generated are from a single photon or multiple photons.

For example, the processor unit is configured to reject charge sharing events or to reconstruct charge sharing events. In the latter case the energy of the reconstructed photon is the sum of the energies of the shared detection events determined from the signal peaks.

According to at least one embodiment, the processor unit is configured to adapt a number of regions of interest or an energy interval of at least one region of interest of each evaluation unit. In particular, the energy interval of a region of interest determines a difference between the upper interest level and the lower interest level, as described for example in paragraphs [0028] to [0030] of U.S. patent application Ser. No. 18/642,373.

According to at least one embodiment, the processor unit is configured to perform at least one of the following operations:
arithmetically processing the number of counts of similar regions of interest of different output signals;
monitoring a variation of the number of counts corresponding to the regions of interest of at least one output signal;
detecting and processing charge sharing events;
adapting a number and/or energy interval of at least one region of interest of each evaluation unit.

In particular, the processor unit is not particularly limited in processing data provided by the evaluation units.

According to at least one embodiment, the processor unit is configured to control the evaluation units and/or at least one detector element. A detector element is in particular formed by a read-out electrode and a semiconductor body corresponding to this read-out electrode. Additionally or alternatively, the processor unit may be configured to read-out, configure, program or synchronize the evaluation units and/or at least one detector element.

For example, the processor unit is configured to provide a control signal for each of the evaluation units and/or detector elements. For example, the evaluation unit, in particular the counter unit of the evaluation unit, may be started, stopped or reset by the processor unit.

In particular, the processor unit may be configured to start and terminate the digitalization step and/or the transferring step of the method for processing the detector signal that is in particular carried out by the evaluation unit.

Preferably, the processor unit is an electronic component distinct from the evaluation units. For example, the processor unit is a CMOS device or a field-programmable gate array (FPGA for short) located either inside and/or outside the detection module.

Furthermore, the processor unit described herein may essentially further comprise similar features as the process unit disclosed in U.S. patent application Ser. No. 18/642,373, and/or may comprise components as disclosed in U.S. patent application Ser. No. 18/642,373, in particular in paragraph [0058].

According to at least one embodiment, each evaluation unit is integrated in an individual electronic component. For example, each evaluation unit is part of an individual electronic component. In other words, the semiconductor detection module comprises a plurality of electronic components, wherein each electronic component comprises exactly one evaluation unit. The electronic components are, for example, microcontrollers or integrated application-specific circuits, ASICs.

According to at least one embodiment, at least some parts of a number of evaluation units are integrated in a common electronic component. For example, at least some or all evaluation units are part of a common electronic component such as an ASIC.

It is also possible that only some components of the evaluation units are part of the common electronic component. For example, storage units of all evaluation units may be part of a common electronic component.

Furthermore, it is possible that the processor unit is an individual electronic component. This means in particular, the processor unit is integrated in an electronic component distinct from the electronic components of each of the evaluation units. The electronic component of the processor unit is preferably a FPGA. Alternatively, the processor unit may be at least partially integrated with at least some parts of at least one evaluation unit.

If at least some parts of a number of evaluation units are integrated in the common electronic component, at least a part of the processor unit may be also integrated in the common electronic component. In a specific example, all evaluation units and the processor unit may be integrated in a single common electronic component.

According to at least one embodiment, the semiconductor detection module comprises a plurality of collimators, wherein each collimator is assigned to exactly one read-out electrode. For example, the read-out electrode may be arranged in an opening of the assigned collimator. Advantageously, charge sharing (crosstalk) between adjacent read-out electrodes can be reduced by using collimators.

According to at least one embodiment, each detector element is configured to receive or detect radiation from a detection area, wherein detection areas corresponding to different detector elements at least partially overlap. For example, all detection areas essentially completely overlap. In other words, the detection module is not configured for spatially resolved detection of electromagnetic radiation. Here and in the following a detection area is a spatial region which can be observed by the corresponding detector element. The detection areas may be defined by a solid angle.

In particular, incident electromagnetic radiation from the detection area can be detected by the corresponding detector element. This means in particular that the detection area may be referred to as a field of view of the corresponding detector element.

Furthermore, a sorting machine is specified. The sorting machine in particular comprises a semiconductor detection module according to one or more of the above-mentioned embodiments. Consequently, all features disclosed for the detection module are also disclosed for the sorting machine and vice versa.

Preferably, the sorting machine comprises the features disclosed for the sorting machine in U.S. patent application Ser. No. 18/642,373, in particular in paragraphs [0067] to [0071].

Furthermore, a spectrometer is specified. The spectrometer in particular comprises a semiconductor detection module according to one or more of the above-mentioned embodiments. Consequently, all features disclosed for the detection module are also disclosed for the spectrometer and vice versa.

In particular, the spectrometer is configured to use X-ray fluorescence to analyze chemical or physical samples. The spectrometer may further comprise an X-ray source configured to irradiate the sample. An X-ray fluorescence of the sample, excited by radiation from the X-ray source, can be detected by the semiconductor detection module.

If, for example, a sample is to be tested for containing particular elements, the regions of interest may be adapted such that the fluorescence radiation generated due to these elements can be detected. If other parts of the fluorescence spectrum, outside the characteristic lines of the particular elements, are not of interest for determining the presence of the particular elements, detecting these parts can be omitted. Thus, only relevant data for determining presence of the particular elements are recorded and processed. Hence, the amount of data can be kept comparably low compared to common comparable detection applications. Hence, the configuration of the semiconductor detection module and its components can be adapted to specific application requirements.

It is further possible that the spectrometer comprises at least one optical element arranged between the X-ray source and/or between the semiconductor detection module. Each optical element may include, but not limited thereto, X-ray optics such as polycapillary tubes, X-ray mirrors, polaristors or the like, and/or beam manipulating elements such as collimators or spectral filters.

It is further possible that the sample is analyzed by a spatially resolved measurement. For example, X-rays from the X-ray source may be focused to a predefined measurement spot which irradiates a predefined part of the sample. To achieve the focused X-rays the spectrometer may comprise at least one optical element. After measuring the predefined measurement spot, the sample and/or the measurement spot may be moved to irradiate a further part of the sample to measure the further part. That is, the sample may be scanned by the focused X-rays to achieve a spatially resolved measurement. In particular, the detection area or detection areas of the detection module are adapted to the scanning procedure, for example by means of at least one optical element.

Furthermore, a synchrotron is specified. The synchrotron in particular comprises a semiconductor detection module according to one or more of the above-mentioned embodiments. Consequently, all features disclosed for the detection module are also disclosed for the synchrotron and vice versa.

Moreover, the semiconductor detection module may be used in various application including the following applications.

In various of the following applications, a fundamental principle of using the semiconductor device is in particular to detect certain elements such as chemical elements, certain materials or traces of certain materials and/or the presence of certain substances, molecules, elements, materials or the like in a variety of samples. An underlying measurement principle in such applications if for example X-ray fluorescence (XRF), where the sample is irradiated with X-rays and a spectral response of the sample is detected and analyzed by the semiconductor detection module.

A main advantage of using the semiconductor module in this application is that high counting rates can be achieved, while geometric dimensions of the semiconductor detection module can be comparably small. Furthermore, due to efficient data processing achieved by the semiconductor detection device, a comparably fast or rapid analysis is possible. In particular, it is possible to carry out a real-time analysis in certain applications.

The semiconductor detection module may be used for process monitoring in industry applications. For example, in metallurgy the semiconductor detection module may be used for real-time analysis of alloy compositions, for example in steel or aluminum production, or for monitoring of melts to adjust the alloy before solidification. For example, in cement production the semiconductor detection module may be used for monitoring of a raw material composition (lime, clay, silicon, iron) in the production process. For example, in glass and ceramics industry the semiconductor detection module may be used for controlling and tracing elements and impurities.

The semiconductor detection module may be used in mining applications and raw material analysis. For example, as described above, in ore sorting applications the semiconductor detection module may be used to distinguish high and low metal content minerals in real time by using high count rate XRF (X-ray fluorescence). For example, for exploration analysis the semiconductor module may be used for rapid chemical analysis of drill core to locate metals such as copper, gold, zinc or nickel. For example, for inline element monitoring the semiconductor module may be used for analyzing the concentration of metals in a conveyor stream.

The semiconductor detection module may be used in recycling applications and scrap analysis. For example, in metal sorting the semiconductor detection module may be used for identification and sorting of precious metals, alloys or specific metals such as aluminum, copper, stainless steel. In particular, accurate results for large quantities of material in a comparably short time can be achieved by the semiconductor detection module since the semiconductor detection module allows for high count rates. For example, in plastic analysis the semiconductor detection module may be used for testing for various additives such as heavy metals, such as lead or cadmium, in recyclable materials.

The semiconductor detection module may be used in thin film and surface analysis applications. For example, in semiconductor manufacturing the semiconductor detection module may be used for measurements of thin films such as metal layers on wafers or printed circuit boards, for example. Furthermore, the semiconductor detection module may be used for an analysis of the chemical composition of ultra-thin layers in production. In addition, the semiconductor detection module may be used for checking the thickness and composition of coatings, for example galvanic coatings comprising gold, silver and/or chromium.

The semiconductor detection module may be used in energy industry applications. For example, for coal analysis the semiconductor detection module may be used for determination of a sulfur content and other trace elements in coal. For example, in nuclear power plant applications the semiconductor detection module may be used for analyzing of materials used in radiation environments, for example reactor materials or protective coatings.

The semiconductor detection module may be used for environmental monitoring. For example, for heavy metal analysis the semiconductor detection module may be used for measuring contaminants such as lead, arsenic or mercury in soil, water or waste. For example, for dust analysis the semiconductor detection module may be used for analysis of airborne dust samples to monitor industrial emissions or workplace safety.

The semiconductor detection module may be used in pharmaceutical and biomedical applications. For example, for purity control the semiconductor detection module may be used for rapid testing of raw materials for traces of impurities or heavy metals. For example, in biological applications the semiconductor detection module may be used for analyzing trace elements in biological samples such as bones or tissues.

### BRIEF DESCRIPTION OF THE DRAWINGS

Further advantages and advantageous embodiments and further developments of the semiconductor detection module described herein will become apparent from the following exemplary embodiments shown in connection with schematic drawings. Identical elements, elements of the same kind or elements having the same effect are provided with the same reference signs in the figures. The figures and the proportions of the elements shown in the figures are not to be regarded as true to scale. Rather, individual elements may be shown exageratedly large for better representability and/or for better comprehensibility.

FIG. 1 shows a block diagram illustrating a semiconductor detection module described herein according to a first exemplary embodiment;

FIGS. 2A to 5B illustrate a semiconductor detection module described herein according to further exemplary embodiments;

FIG. 6 illustrates a sorting machine described herein according to an exemplary embodiment; and

FIGS. 7 to 9 illustrate spectrometers described herein according to exemplary embodiments.

### DETAILED DESCRIPTION OF ILLUSTRATIVE EMBODIMENTS

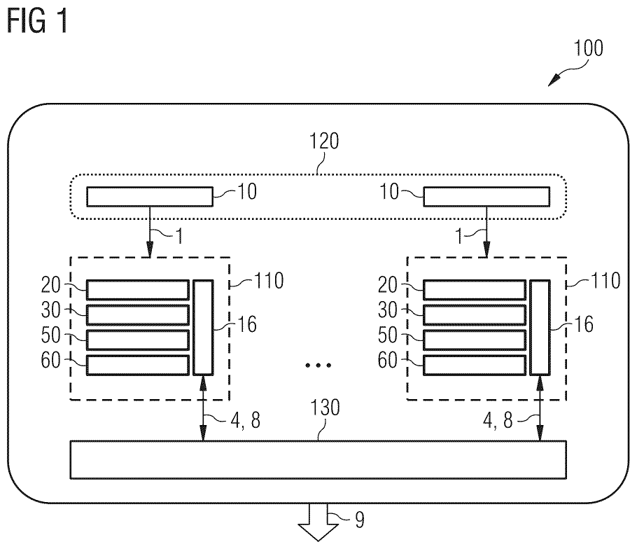

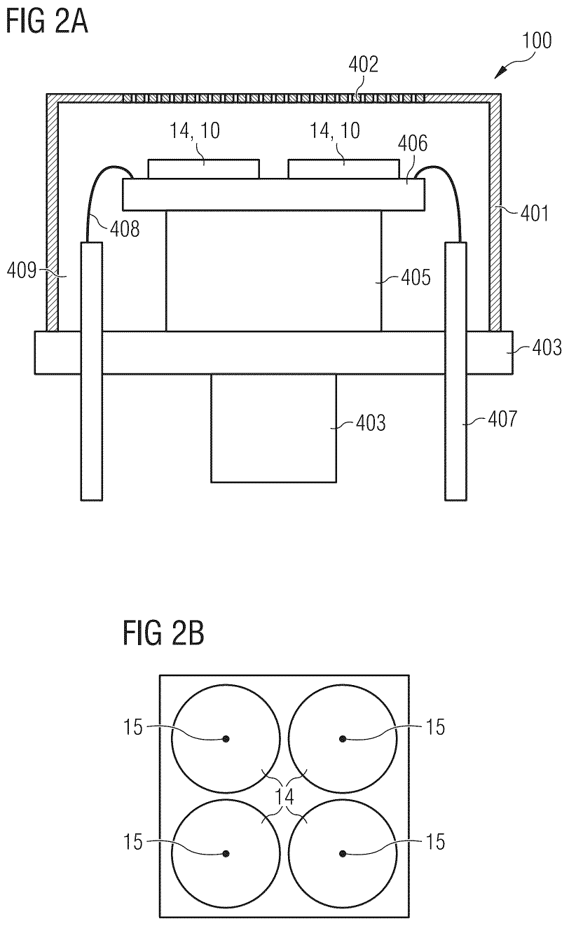

FIG. 1 illustrates a semiconductor detection module 100 described herein according to a first exemplary embodiment. The detection module 100 comprises a detector unit 120. The detector unit 120 comprises a plurality of detector elements 10. Each detector element 10 comprises a semiconductor body 14 and a read-out electrode 15, as illustrated, for example, in FIG. 2. It is possible that a common semiconductor body 14 extends over a plurality of detector elements 10. Alternatively, each detector element 10 comprises an individual semiconductor body 14. However, each detector element 10 comprises exactly one read-out electrode 15.

The detector unit 120 and each detector element 10 are configured to detect incident electromagnetic radiation, in particular X-rays. For example, each detector element 10 is configured to detect X-rays incident from a detection area. The detection areas corresponding to different detector elements 10 partially or preferably essentially completely overlap. Thus, a maximum counting rate of the semiconductor detection module 100 can be increased.

The semiconductor body 14 is, for example, based on n-doped silicon.

During operation, an electrical drift field is generated in the semiconductor body 14 of each detector element 10. Incident radiation generates free charge carriers in the semiconductor body 14, which are guided to the read-out electrode 15 by the drift field. For example, the read-out electrode 15 is an anode. Preferably, each detector element 10 acts as or forms a silicon drift detector.

At the read-out electrode 15 charge carriers are accumulated and a signal peak is obtained. A height and/or area of the signal peak in particular corresponds to an energy of the incident photon causing the generation of the free charge carriers. The read-out electrode 15 provides a detector signal 1 comprising a sequence of such signal peaks, wherein each signal peak corresponds to one detection event.

The semiconductor detection module 100 further comprises a plurality of evaluation units 110 configured to receive the detector signals 1 provided by each detector element 10. This means that a number of evaluation units 110 equals a number of detector elements 10 or read-out electrodes 15.

Each evaluation unit 110 comprises an integration unit 20, a shaping unit 30, a comparator unit 50 and a counter unit 60 and is configured to generate an output signal 4 from the detector signal 1. In particular, each of the shaping unit 30, the comparator unit 50 and the counter unit 60 may be integrated in one electronic component or chip. It is also possible that at least some of the shaping unit 30, the comparator unit 50 and the counter unit 60 are integrated in a common electronic component or chip. That is, it is possible that the evaluation unit 110 may be formed as one or more electronic components or chips.

Each evaluation unit 110 is configured to process the raw detector signal 1 comprising the sequence of signal peaks by assigning the signal peaks to at least one region of interest. Each evaluation unit 110 is further configured to provide a number of counts in each region of interest as an output signal 4. In particular, the signal peaks are assigned or binned to the regions of interest based on the height and/or the area of the signal peak. In other words, the signal peaks are in particular binned depending on the energy of the detected photon to which the signal peak corresponds. The number of counts in particular corresponds to the number of signal peaks assigned to a certain region of interest.

Each evaluation unit 110 is configured to carry out a method for processing a detector signal as described in U.S. patent application Ser. No. 18/642,373.

In particular, the evaluation unit is configured to perform the method for processing the detector signal according to one or more of the embodiments disclosed in paragraphs [0003] to [0039] and/or one or more exemplary embodiments of FIGS. 1 to 7 and paragraphs [0078] to [0095] of U.S. patent application Ser. No. 18/642,373.

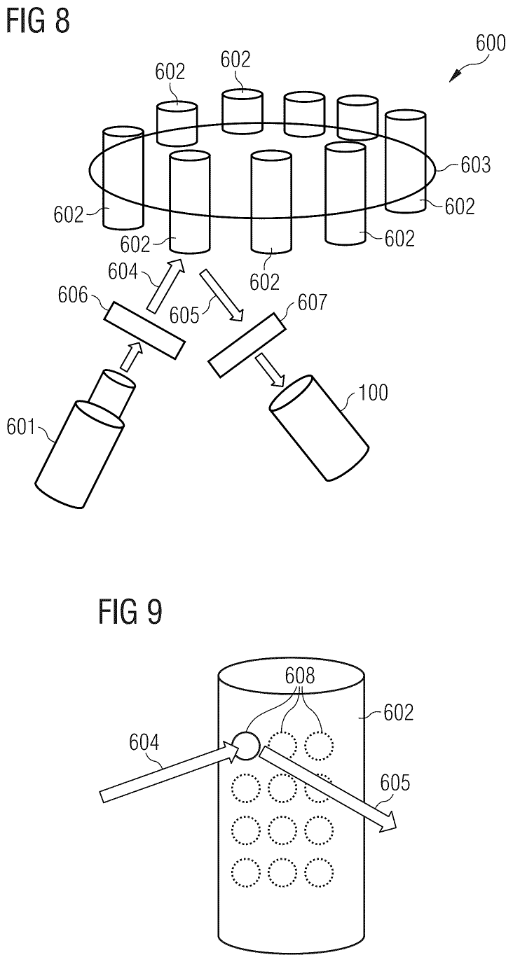

Furthermore, each evaluation unit 110 may be formed and comprise components and/or features as disclosed in paragraphs [0096] to [0124] and FIGS. 8 to 14 of U.S. patent application Ser. No. 18/642,373. Moreover, the evaluation unit 110 and semiconductor detection module 100 may additionally essentially comprise similar features as the evaluation unit 110 and the detection module 100 disclosed in U.S. patent application Ser. No. 18/642,373, respectively, and/or may comprise components as disclosed in U.S. patent application Ser. No. 18/642,373, in particular in paragraphs [0041] to [0066].

Each of the evaluation units 110 may be an application-specific integrated circuit, ASIC. Each evaluation unit 110 may optionally comprise a control unit 16 configured to control the evaluation unit 110. The control unit 16 may receive a control signal 8. In particular, by the control signal 8 interest levels of the regions of interests may be adjusted in particular dependent on the application.

The semiconductor detection module 100 further comprises a processor unit 130. In the present exemplary embodiment the processor unit 130 is a field-programmable gate array, FPGA for short. In other exemplary embodiments the processor unit 130 may be a microcontroller or an ASIC.

The processor unit 130 is configured to process the output signals 4 and to provide a single processed data signal 9. The single processed data signal 9 is in particular a total output of the detection module 100. Thus, the semiconductor detection module 100 may provide the single data signal 9 as a one-channel output.

The processor unit 130 may process output signals 4 from a plurality of evaluation units 110 as illustrated in FIG. 1. That is, the processor unit 130 is configured to receive the output signals 4 as an input, process the output signals 4 by, for example, arithmetic or other procedures, and provide the single data signal 9 as an output. In this case, the processor unit 130 is preferably an individual electronic component that is separated from electronic components of the evaluation units.

The processor unit 130 is further configured to control operations of the evaluation units 110 by providing the control signal 8 to the control units 16. For example, the processor unit 130 may start, stop or reset the counter units 60 of the evaluation units 110.

Furthermore, the processor unit 130 may read-out and/or process the number of counts provided by the evaluation units 110, in particular as the output signals 4. For example, the processor unit 130 is configured to arithmetically process the number of counts of similar regions of interest of different output signals 4. For example, the processor unit 130 may be configured to calculate an average or sum of the number of counts of each region of interest, taking into account the number of counts of each output signal 4. In particular, the processor unit 130 is configured to perform any numerical operation reasonable to process the output signals 4.

By using the semiconductor detection module 100 according to the first exemplary embodiment, a maximal counting rate can be increased compared to common comparable semiconductor detectors. Typically, counting rates of a semiconductor detector such as a silicon drift detector are in particular limited by a pulse length of a pulse corresponding to a detection event after signal shaping. In particular, a maximal counting rate is limited to a reciprocal of the pulse length.

The semiconductor detection module 100 provides a plurality of read-out electrodes 15, each providing a detector signal 1. If, for example, N read-out electrodes 15 are provided, the maximal counting rate Zₘₐₓ may be determined by N/tₚ, where tₚ denotes the pulse length. However, by increasing the number of read-out electrodes 15 and detector signals 1, an amount of data to be processed to analyze the incident radiation also significantly increases.

By using the evaluation unit 110, the amount of data to be processed can be significantly reduced, since only signal peaks of the detector signals 1 corresponding to regions of interest are considered, as described in paragraphs to [0016] of U.S. patent application Ser. No. 18/642,373.

As a consequence, the amount of data generated by the read-out electrodes 15 and the evaluation unit 110 is comparably low and can be even further processed and condensed by the processor unit 130 so that as a total output a single-channel data signal 9 can be provided. Thus, advantageously only minor adaptions of applications are necessary if the semiconductor detection module 100 is used instead of common semiconductor detectors.

FIGS. 2A and 2B illustrate a semiconductor detection module 100 according to a second exemplary embodiment in a schematic sectional view (FIG. 2A) and a schematic top view (FIG. 2B). Detector elements 10 of the detection module 100 are arranged in a housing comprising a housing cap 401 and a socket 403, defining an enclosed space 409. The enclosed space 409 can be filled with a gas such as air or an inert gas or may enclose a vacuum.

In the second exemplary embodiment, each detector element 10 comprises a semiconductor body 14 and a read-out electrode 15 as illustrated in FIG. 2B.

The detector elements 10 are arranged on an electronic system 406, which may comprise the evaluation units 110 and the processor unit 130. For example, the electronic system may comprise a carrier for the detector elements 10 and a plurality of ASICs comprising the evaluation units 110, and an FPGA comprising the processor unit 130.

The electronic system 406 is contacted by connection wires 408 connected to through-connections 407 extending through the socket 403 into the enclosed space 409.

In other aspects, in particular in terms of its functionality and technical effects, the semiconductor detection module 100 according to the exemplary embodiment of FIGS. 2A and 2B comprises essentially the same features as the exemplary embodiment according to FIG. 1.

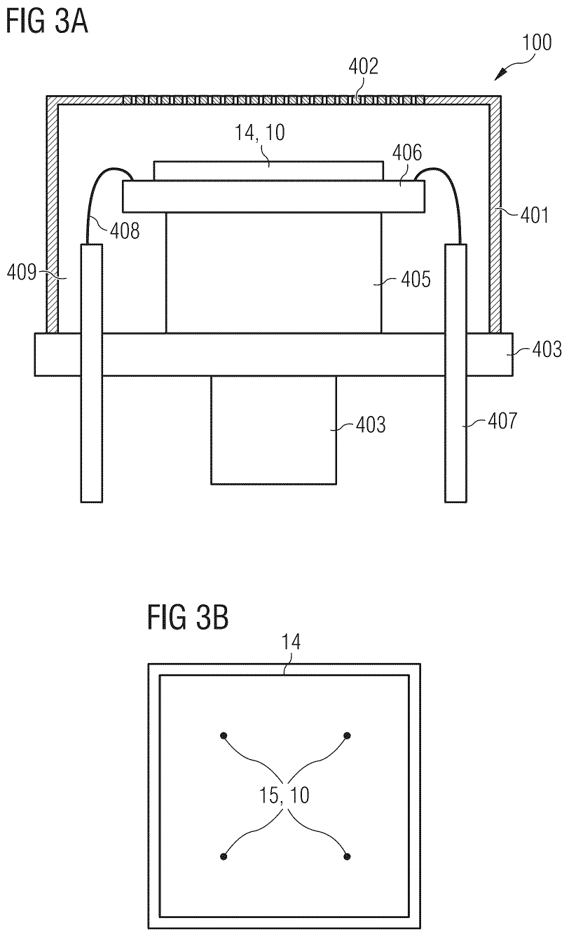

FIGS. 3A and 3B illustrate a semiconductor detection module 100 according to a third exemplary embodiment in a schematic sectional view (FIG. 3A) and a schematic top view (FIG. 3B). In contrast to FIGS. 2A and 2B, the semiconductor detection module 100 according to FIGS. 3A and 3B comprises a common semiconductor body 14 for all detector elements 10. This means that the read-out electrodes 15 are all assigned to one common semiconductor body 14. In this exemplary embodiment, the detector elements 10 are defined by the plurality of read-out electrodes 15.

In other aspects, in particular in terms of its functionality and technical effects, the semiconductor detection module 100 according to the exemplary embodiment of FIGS. 3A and 3B comprises essentially the same features as the exemplary embodiment according to FIGS. 2A and 2B.

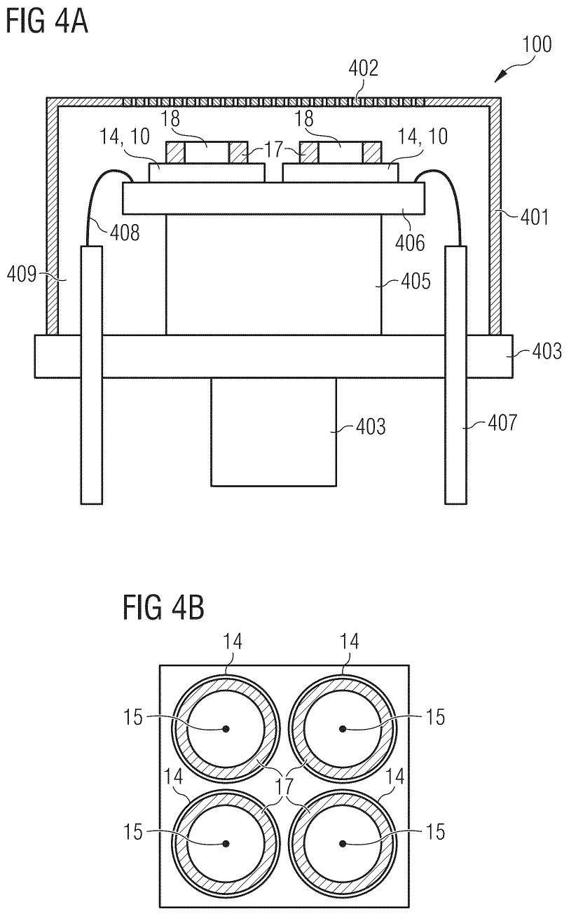

FIGS. 4A and 4B illustrate a semiconductor detection module 100 according to a fourth exemplary embodiment in a schematic sectional view (FIG. 4A) and a schematic top view (FIG. 4B). In contrast to FIGS. 2A and 2B, the semiconductor detection module 100 according to FIGS. 4A and 4B comprises collimators 17 for all detector elements 10. Each collimator 17 comprises an opening 18, in which a read-out electrode 15 of the respective detector element 10 is arranged. Crosstalk between different detector elements 10 can be reduced by using the collimators 17. As a result, a detection performance of the detector elements 10 can be increased.

In other aspects, in particular in terms of its functionality and technical effects, the semiconductor detection module 100 according to the exemplary embodiment of FIGS. 4A and 4B comprises essentially the same features as the exemplary embodiment according to FIGS. 2A and 2B.

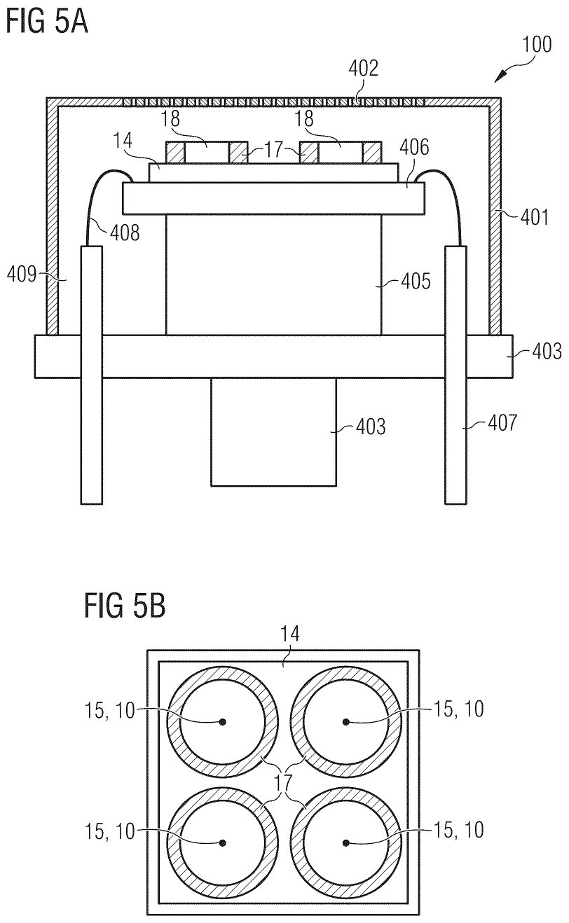

FIGS. 5A and 5B illustrate a semiconductor detection module 100 according to a fifth exemplary embodiment in a schematic sectional view (FIG. 5A) and a schematic top view (FIG. 5B). In contrast to FIGS. 4A and 4B, the semiconductor detection module 100 according to FIGS. 5A and 5B comprises a common semiconductor body 14 for all detector elements 10. This means that the read-out electrodes 15 are all assigned to one common semiconductor body 14. In this exemplary embodiment, the detector elements 10 are defined by the plurality of read-out electrodes 15.

In other aspects, in particular in terms of its functionality and technical effects, the semiconductor detection module 100 according to the exemplary embodiment of FIGS. 5A and 5B comprises essentially the same features as the exemplary embodiment according to FIGS. 2A and 2B.

In the exemplary embodiments of FIGS. 2A to 5B, each detection module 100 comprises four detector elements 10 and four read-out electrodes 14 for illustration. However, the detection module 100 according to this disclosure is not particularly limited to a certain number of detector elements 10 and/or read-out electrodes 14. In particular, the detection module 100 according to the present disclosure may comprise a plurality of detector elements 10 and/or read-out electrodes 14, wherein the number of detector elements 10 and/or read-out electrodes 14 may in particular be adapted for an application in which the detection module 100 may be used.

Furthermore, in the exemplary embodiments of FIGS. 4A to 5B, the detector elements 10 may be regarded to have a round shape in top view (FIG. 4B, FIG. 5B). However, the shape of the detector elements 10 is not particularly limited thereto. In particular, the detection module 100 according to the present disclosure may comprise detector elements 10 with any geometrical shape, wherein the geometrical shape is preferably adapted for an application in which the detection module 100 may be used.

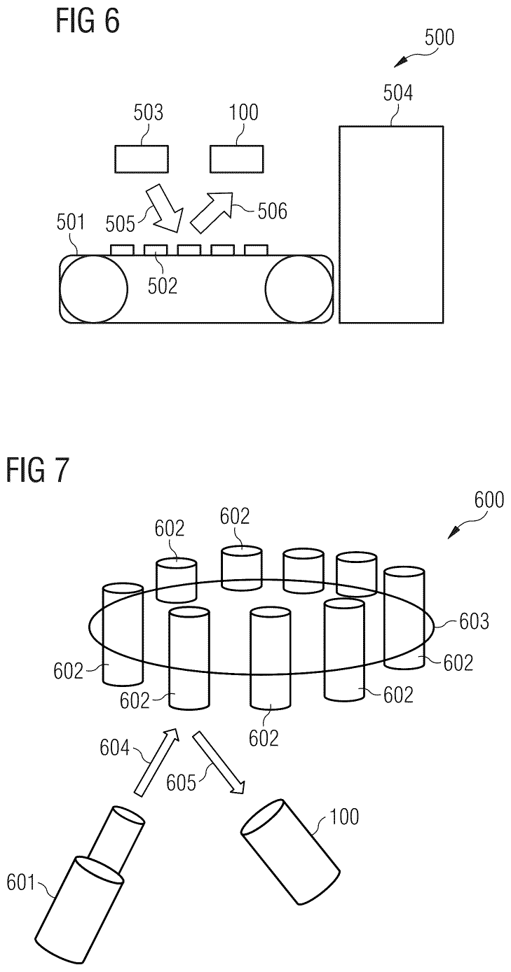

FIG. 6 illustrates a sorting machine 500 described herein according to an exemplary embodiment. The sorting machine 500 comprises a conveyer band 501 on which material to be sorted 502 is arranged. The material to be sorted 502 is illuminated by X-rays 505 from an X-ray source 503 during operation. The X-ray source 503 is, for example, an X-ray tube.

The sorting machine 500 further comprises a detection module 100 according to an exemplary embodiment described above. X-rays that emerge from the material 506 are detected by the detection module 100. By means of XRF, a material composition of the material 502 can be obtained. A sorting device 504 sorts the material 502 according to its material composition.

For example, some of the material 502 comprises a specific element, such as a chemical element, or molecule or composition. In order to separate the material 502 with the specific composition from the other material, the material composition of the material is analyzed by XRF.

In particular, regions of interest of the detection module 100 are adapted to characteristic lines or peaks of the specific element or molecule or composition. Hence, it is not necessary to generate a whole XRF spectrum. Therefore, the sorting of the material 502 can be carried out in a cheaper and faster manner.

By the detection module 100, the specific composition is detected, and the sorting device 504 separates the material 502 with the specific composition from the other material.

The material may comprise ores, scraps to be recycled or the like. By the sorting machine 500, the ore may be analyzed with respect to its material composition. Ore comprising a desired material or chemical element such as a certain metal under or above a certain concentration level may be removed.

FIG. 7 illustrates a spectrometer 600 described herein according to an exemplary embodiment. The spectrometer 600 comprises a sample holder 603, on which a plurality of samples 602 to be analyzed are arranged. Certain samples 602 are illuminated by X-rays 604 from an X-ray source 601 during operation. The X-ray source 601 is, for example, an X-ray tube. The sample holder 603 may rotate so that the samples 602 are sequentially exposed to X-rays 604 from the X-ray source 601.

The spectrometer 600 further comprises a detection module 100 according to an exemplary embodiment described above. X-rays 605 that emerge from each sample 602 is detected by the detection module 100. By means of XRF, a material composition of the samples 602 can be analyzed.

For example, the samples 602 are tested for comprising a certain element, material or molecule. In order to determine the presence of the certain chemical element, material or molecule, the samples are analyzed by XRF.

In particular, regions of interest of the detection module 100 are adapted to characteristic lines or peaks of the specific element or molecule or material. Hence, it is not necessary to generate a whole XRF spectrum. Therefore, the analyzing of the samples 602 can be carried out in a cheaper and faster manner and at high counting rates.

FIG. 8 illustrates a spectrometer 600 according to a further exemplary embodiment. The spectrometer 600 according to FIG. 8 comprises essentially the same features as the spectrometer according to FIG. 7 with the difference that the spectrometer 600 of FIG. 8 comprises a first optical element 606 and a second optical element 607.

The first optical element 606 is arranged between the X-ray source 601 and the sample 602. The second optical element 607 is arranged between the sample 602 and the detection module 100. Each of the optical elements 606, 607 may be an X-ray optics such as a polycapillary tubes, X-ray mirrors, polarisators or the like. Additionally or alternatively, the first optical element 606 and/or the second element 607 may be configured for beam manipulation and may comprise a collimator or spectral filters.

By the optical elements 606, 607, the intensity of the X-rays at the sample 602 and/or at the detection module 100 may be increased, respectively.

For example, the first optical element 606 is configured to focus X-rays 604 of the X-ray source 602 at a measurement spot, which defines a sample detection area 608, as shown in FIG. 9. The detection module 100 is configured to detect X-rays 605 from the sample detection area 608. After measuring the sample detection area 608, the measurement spot may be moved to another sample detection area 608, as illustrated in FIG. 9 by the dashed lines. Thus, a spatially resolved measurement is possible.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A semiconductor detection module comprising:
at least one semiconductor body;
a plurality of read-out electrodes assigned to the at least one semiconductor body and configured to provide one raw detector signal per read-out electrode; and
a plurality of evaluation units, each evaluation unit configured to process the raw detector signal, which comprises a sequence of signal peaks, by assigning the signal peaks to at least one region of interest and to provide a number of counts in each region of interest as an output signal,
wherein each evaluation unit is assigned to exactly one read-out electrode.

2. The semiconductor detection module according to claim 1, wherein the at least one semiconductor body is a plurality of semiconductor bodies, and wherein at least one read-out electrode is assigned to each semiconductor body.

3. The semiconductor detection module according to claim 2, wherein a number of semiconductor bodies equals a number of read-out electrodes so that each semiconductor body is assigned to exactly one read-out electrode.

4. The semiconductor detection module according to claim 1, further comprising a processor unit configured to process the output signals and to provide a single processed data signal.

5. The semiconductor detection module according to claim 4, wherein the processor unit is configured to perform at least one of the following operations:
arithmetically processing the number of counts of similar regions of interest of different output signals;
monitoring a variation of the number of counts corresponding to the regions of interest of at least one output signal;
detecting and processing charge sharing events;
adapting a number and/or energy interval of at least one region of interest of each evaluation unit.

6. The semiconductor detection module according to claim 4, wherein the processor unit is configured to control the evaluation units and/or at least one detector element, each detector element comprising at least one semiconductor body and one of the read-out electrodes.

7. The semiconductor detection module according to claim 1, wherein each of the evaluation units is integrated in an individual electronic component.

8. The semiconductor detection module according to claim 1, wherein at least some parts of a number of evaluation units are integrated in a common electronic component.

9. The semiconductor detection module according to claim 1, further comprising a plurality of collimators, wherein each collimator is assigned to exactly one read-out electrode.

10. The semiconductor detection module according to claim 1,
wherein each detector element, comprising at least one semiconductor body and one of the read-out electrodes, is configured to receive radiation from a detection area, and
wherein detection areas of all detector elements at least partially overlap.

11. A sorting machine comprising:
the semiconductor detection module according to claim 1.

12. A spectrometer using X-ray fluorescence and comprising:
the semiconductor detection module according to claim 1.

13. A synchrotron comprising:
the semiconductor detection module according to claim 1.
